(19) United States
(12) Patent Application Publication
(10) Pub. No.: US 2026/0018858 A1
(43) Pub. Date: Jan. 15, 2026

(54) SEMICONDUCTOR LASER DEVICE

(71) Applicants: SUMITOMO ELECTRIC INDUSTRIES, LTD., Osaka (JP); SUMITOMO ELECTRIC DEVICE INNOVATIONS, INC., Yokohama-shi (JP)

(72) Inventors: Daisuke INOUE, Osaka-shi (JP); Konosuke AOYAMA, Yokohama-shi (JP)

(73) Assignees: SUMITOMO ELECTRIC INDUSTRIES, LTD., Osaka (JP); SUMITOMO ELECTRIC DEVICE INNOVATIONS, INC., Yokohama-shi (JP)

(21) Appl. No.: 19/259,843

(22) Filed: Jul. 3, 2025

(30) Foreign Application Priority Data
Jul. 12, 2024 (JP) 2024-112704

(51) Int. Cl. H01S 5/026; H01S 5/12; H01S 5/227; H01S 5/50

(52) U.S. Cl. CPC H01S 5/0261; H01S 5/12; H01S 5/227; H01S 5/50

(57) ABSTRACT

A semiconductor laser device includes a laser region that causes light to perform laser oscillation, an amplifier region adjacent to the laser region and amplifies the light, and a resistor provided in the laser region and heats the laser region. The resistor has at least one first portion and at least one second portion. The at least one second portion is connected to the at least one first portion and is closer to a boundary between the laser region and the amplifier region than the first portion. A resistance per unit length of the at least one second portion is higher than a resistance per unit length of the at least one first portion.

### CROSS REFERENCE TO RELATED APPLICATIONS

This application claims priority based on Japanese Patent Application No. 2024-112704 filed on Jul. 12, 2024, and the entire contents of the Japanese patent application are incorporated herein by reference.

### TECHNICAL FIELD

The present disclosure relates to a semiconductor laser device.

### BACKGROUND

Some semiconductor laser devices are formed by integrating a plurality of devices. For example, a device in which a distributed Bragg reflector (DBR) laser and a region for adjusting a phase are integrated is known (Non-patent literature 1: T. Kameda et al. “A DBR Laser Employing Passive-Section Heaters, with 10.8 nm Tuning Range and 1.6 MHz Linewidth” IEEE Photonics Technology Letters, Vol.5, No.6, pp. 608-610, June 1993). A heater is provided in the phase adjustment region to control the temperature, thereby adjusting the phase of the light.

### SUMMARY

A semiconductor laser device according to the present disclosure includes a laser region configured to cause light to perform laser oscillation, an amplifier region adjacent to the laser region and configured to amplify the light, and a resistor provided in the laser region and configured to heat the laser region. The resistor has at least one first portion and at least one second portion. The at least one second portion is connected to the at least one first portion and is closer to a boundary between the laser region and the amplifier region than the first portion. A resistance per unit length of the at least one second portion is higher than a resistance per unit length of the at least one first portion.

### BRIEF DESCRIPTION OF THE DRAWINGS

FIG. 1 is a plan view illustrating a semiconductor laser device according to a first embodiment.

FIG. 2A is a cross-sectional view illustrating a semiconductor laser device.

FIG. 2B is a cross-sectional view illustrating a semiconductor laser device.

FIG. 3 is a cross-sectional view illustrating a semiconductor laser device.

FIG. 4A is a diagram illustrating heating efficiency.

FIG. 4B is a diagram illustrating electric power.

FIG. 5 is a plan view illustrating a semiconductor laser device according to a comparative example.

FIG. 6 is a diagram illustrating a temperature distribution.

FIG. 7A is a cross-sectional view illustrating a manufacturing method of a semiconductor laser device.

FIG. 7B is a cross-sectional view illustrating a manufacturing method of a semiconductor laser device.

FIG. 7C is a cross-sectional view illustrating a manufacturing method of a semiconductor laser device.

FIG. 8A is a cross-sectional view illustrating a manufacturing method of a semiconductor laser device.

FIG. 8B is a cross-sectional view illustrating a manufacturing method of a semiconductor laser device.

FIG. 8C is a cross-sectional view illustrating a manufacturing method of a semiconductor laser device.

FIG. 9A is a cross-sectional view illustrating a manufacturing method of a semiconductor laser device.

FIG. 9B is a cross-sectional view illustrating a manufacturing method of a semiconductor laser device.

FIG. 9C is a cross-sectional view illustrating a manufacturing method of a semiconductor laser device.

FIG. 10 is a cross-sectional view illustrating a semiconductor laser device according to a modification.

FIG. 11 is a plan view illustrating a semiconductor laser device according to a second embodiment.

FIG. 12 is a plan view illustrating a semiconductor laser device according to a third embodiment.

FIG. 13 is a plan view illustrating a semiconductor laser device according to a fourth embodiment.

FIG. 14 is a plan view illustrating a semiconductor laser device according to a fifth embodiment.

### DETAILED DESCRIPTION

A device in which a distributed feedback (DFB) laser and a semiconductor optical amplifier (SOA) for amplifying light are integrated has also been developed. The temperature of the laser region is controlled by using a heater provided in the laser region, and the wavelength of a laser beam is changed. In order to stably control the wavelength, the laser region may be uniformly heated. However, the temperature of the SOA may rise and optical output may decrease. Thus, an object of the present disclosure is to provide a semiconductor laser device capable of controlling wavelength of light and improving optical output.

### Description of Embodiments of Present Disclosure

First, the contents of embodiments of the present disclosure will be listed and explained.
(1) A semiconductor laser device according to an aspect of the present disclosure includes a laser region configured to cause light to perform laser oscillation, an amplifier region adjacent to the laser region and configured to amplify the light, and a resistor provided in the laser region and configured to heat the laser region. The resistor has at least one first portion and at least one second portion. The at least one second portion is connected to the at least one first portion and is closer to a boundary between the laser region and the amplifier region than the first portion. A resistance per unit length of the at least one second portion is higher than a resistance per unit length of the at least one first portion. A portion of the laser region near the boundary between the laser region and the amplifier region is strongly heated. The temperature is low in the amplifier region, rapidly rises near the boundary, and is high in the laser region. It is possible to control wavelength of light and improve optical output.
(2) In the above (1), the at least one first portion may have a width greater than a width of the at least one second portion. The resistance per unit length of the second portion is higher than the resistance per unit length of the first portion. It is possible to control wavelength of light and improve optical output.
(3) In the above (1) or (2), the at least one second portion may include a tapered portion. The tapered portion may have a width that decreases from the laser region toward the amplifier region. The resistance per unit length of the second portion is higher than the resistance per unit length of the first portion. It is possible to control wavelength of light and improve optical output.
(4) In any one of the above (1) to (3), the at least one second portion may be provided in the laser region. The at least one second portion may have an end portion located at the boundary between the laser region and the amplifier region. Since the temperature of the amplifier region is less likely to rise, optical output can be improved. Wavelength of light can be controlled by changing the temperature of the laser region.
(5) In any one of the above (1) to (3), the at least one second portion may be provided in the laser region and the amplifier region. The temperature is uniformly changed by uniformly heating the laser region. Wavelength of light can be controlled with high accuracy.
(6) In any one of the above (1) to (5), the at least one first portion and the at least one second portion may include two first portions and two second portions, respectively. One of the two first portions and one of the two second portions may be connected to each other. The one of the two second portions and another one of the two second portions may be connected to each other. The another one of the two second portions and another one of the two first portions may be connected to each other. It is possible to control wavelength of light and improve optical output.
(7) In any one of the above (1) to (6), the at least one first portion may be longer than the at least one second portion in an extending direction of the laser region. The temperature of the entire laser region can be controlled to set wavelength to a desired value.
(8) In any one of the above (1) to (7), the semiconductor laser device may further include a first semiconductor layer provided in the laser region and the amplifier region; and a second semiconductor layer provided in the laser region and embedded in the first semiconductor layer. A portion in which the first semiconductor layer and the second semiconductor layer are alternately arranged may be configured to form a diffraction grating. Wavelength of light can be controlled by changing the temperature of the diffraction grating by the resistor and adjusting a refractive index.
(9) In the above (8), the semiconductor laser device may further include an active layer stacked above the first semiconductor layer, and a third semiconductor layer stacked above the active layer. The first semiconductor layer may have a first conductivity type. The third semiconductor layer may have a second conductivity type. The first semiconductor layer and the active layer may be configured to form a mesa. The mesa may extend to the laser region and the amplifier region. The third semiconductor layer may be provided on the mesa. The resistor may be provided above the third semiconductor layer and at a position directly above the mesa or at a position away from the mesa.

### Details of Embodiments of Present Disclosure

Specific examples of a semiconductor laser device according to embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

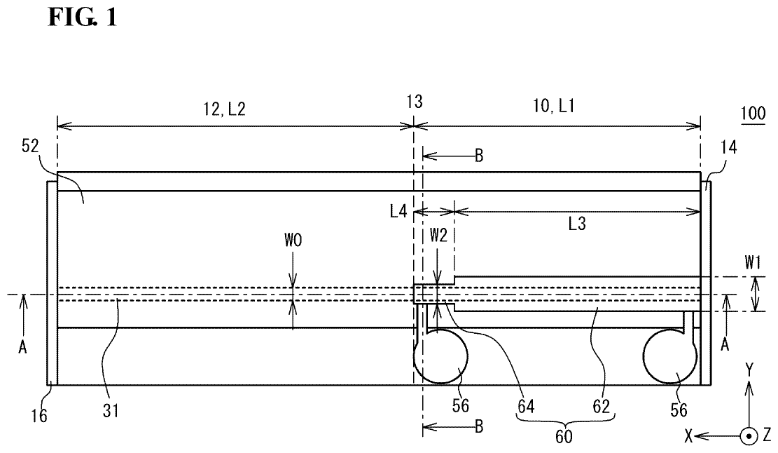

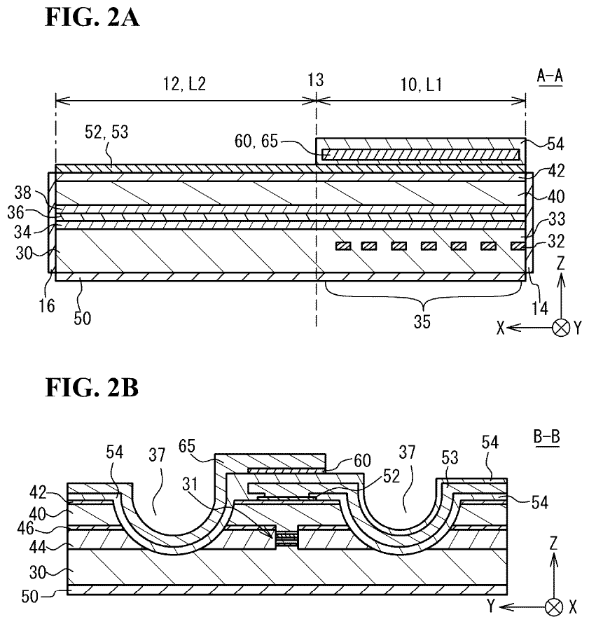

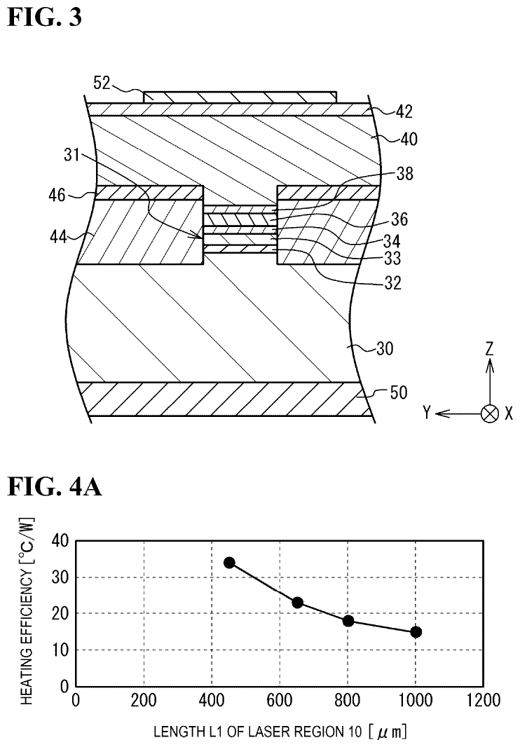

FIG. 1 is a plan view illustrating a semiconductor laser device 100 according to an embodiment. FIG. 2A to FIG. 3 are cross-sectional views each illustrating the semiconductor laser device 100. An X-axis direction is a direction of propagation of light. A Y-axis direction is a width direction. A Z-axis direction is a thickness direction. The X-axis direction, the Y-axis direction, and the Z-axis direction are orthogonal to each other.

As shown in FIG. 1, the semiconductor laser device 100 is a device in which a DFB laser and an SOA are integrated. That is, the semiconductor laser device 100 includes a laser region 10 that functions as a DFB laser and an amplifier region 12 that functions as an SOA. The dashed line in FIG. 1 represents a boundary 13 between the laser region 10 and the amplifier region 12. The laser region 10 and the amplifier region 12 extend parallel to the X-axis direction and are adjacent to each other. A length of the laser region 10 in the X-axis direction is defined as L1. A length of the amplifier region 12 in the X-axis direction is defined as L2.

A high-reflection coating (HR coating) 14 and an anti-reflection coating (AR coating) 16 are provided on end faces of the semiconductor laser device 100, respectively. The high-reflection coating 14 is provided on a surface of the laser region 10 opposite to the amplifier region 12. The anti-reflection coating 16 is provided on a surface of the amplifier region 12 opposite to the laser region 10.

The semiconductor laser device 100 has a mesa 31. The mesa 31 extends in the X-axis direction. The mesa 31 is provided in the laser region 10 and the amplifier region 12, and extends in the X-axis direction from the end face of the semiconductor laser device 100 in contact with the high-reflection coating 14 to the end face in contact with the anti-reflection coating 16. A width WO of the mesa 31 is, for example, 2 μm. Light propagates through the mesa 31. The light is laser-oscillated in the laser region 10. A laser beam is amplified in the amplifier region 12.

FIG. 2A shows a cross-section taken along line A-A of FIG. 1. FIG. 2B shows a cross-section taken along line B-B of FIG. 1. FIG. 3 is an enlarged view of a part of FIG. 2B. As shown in FIG. 2A, the semiconductor laser device 100 includes a substrate 30, a semiconductor layer 32, a cladding layer 33, a light confinement layer 34, an active layer 36, a light confinement layer 38, a cladding layer 40, and a contact layer 42. On one surface of the substrate 30, the cladding layer 33, the light confinement layer 34, the active layer 36, the light confinement layer 38, the cladding layer 40, and the contact layer 42 are stacked in order in the Z-axis direction. The cladding layer 33 corresponds to a first semiconductor layer. The cladding layer 40 and the contact layer 42 correspond to a third semiconductor layer.

The semiconductor layer 32 (second semiconductor layer) is embedded in a portion of the cladding layer 33 included in the laser region 10. A plurality of semiconductor layers 32 are periodically arranged along the X-axis direction. In the laser region 10, the cladding layers 33 and the semiconductor layers 32 are alternately arranged to form a diffraction grating 35. The semiconductor layer 32 is not provided in the amplifier region 12. The diffraction grating 35 is provided in the laser region 10, and is not provided in the amplifier region 12.

As shown in FIG. 2B, the semiconductor laser device 100 includes the mesa 31 and trenches 37. The trenches 37 are provided on both sides of the mesa 31 in the Y-axis direction.

As shown in FIG. 3, the center portion of the substrate 30 in the Y-axis direction is protruding in the Z-axis direction as compared to a portion outside the center portion of the substrate 30. In the center portion of the substrate 30, the semiconductor layer 32, the cladding layer 33, the light confinement layer 34, the active layer 36, the light confinement layer 38, the cladding layer 40, and the contact layer 42 are stacked. The layers from the center portion of the substrate 30 to the light confinement layer 38 form the mesa 31. A semiconductor layer 44 and a semiconductor layer 46 are stacked on both sides of the mesa 31 in the Y-axis direction. The semiconductor layer 44 and the semiconductor layer 46 form an embedding structure. The cladding layer 40 is provided on the mesa 31 and the semiconductor layer 46. The contact layer 42 is provided on the cladding layer 40.

As shown in FIG. 2B, the trench 37 is a portion recessed in the Z-axis direction, and extending partway into the substrate 30 through the semiconductor layers from the contact layer 42 to the semiconductor layer 44. The semiconductor layer 44, the semiconductor layer 46, the cladding layer 40, and the contact layer 42 are provided outside the trench 37 in the Y-axis direction. The mesa 31, the inside of the trench 37, and the portion outside the trench 37 are covered with an insulating film 54. The insulating film 54 has an opening above the mesa 31. The insulating film 54 is formed of an insulating material such as silicon oxide (SiO₂) and silicon nitride (SiN).

The substrate 30 is a semiconductor substrate and is formed of, for example, n-type (first conductivity type) indium phosphide (n-InP). The semiconductor layer 32 is formed of, for example, n-type indium gallium arsenide phosphide (n-InGaAsP). The emission wavelength of the semiconductor layer 32 is, for example, 1.0 μm to 1.15 μm. The cladding layer 33 is formed of, for example, n-InP. The substrate 30, the semiconductor layer 32, and the cladding layer 33 are doped with, for example, silicon (Si). The refractive index of the semiconductor layer 32 is different from the refractive index of each of the substrate 30 and the cladding layer 33.

The active layer 36 has a quantum well (MQW: Multi Quantum Well) structure, and includes a plurality of well layers and a plurality of barrier layers. The plurality of well layers and the plurality of barrier layers are alternately stacked. The well layers and the barrier layers are formed of, for example, undoped InGaAsP. The emission wavelength is, for example, 1.25 μm to 1.6 μm. The light confinement layer 34 and the light confinement layer 38 are formed of, for example, InGaAsP. The refractive index of each of the light confinement layer 34 and the light confinement layer 38 is lower than the refractive index of the active layer 36 and higher than the refractive index of each of the cladding layer 33 and the cladding layer 40. The active layer 36, the light confinement layer 34, and the light confinement layer 38 form a separate confinement heterostructure (SCH).

The cladding layer 40 is formed of, for example, p-type (second conductivity type) indium phosphide (p-InP). The contact layer 42 includes a p-InGaAs layer and a p-InGaAsP layer. The p-InGaAs layer and the p-InGaAsP layer are stacked in this order on the cladding layer 40. The p-type semiconductor layer is doped with, for example, zinc (Zn).

The semiconductor layer 44 is formed of, for example, p-InP. The semiconductor layer 46 is formed of, for example, n-InP.

As shown in FIG. 2A, the semiconductor laser device 100 includes an electrode 50, an electrode 52, and a heater 60. The electrode 50 and the electrode 52 are provided in the laser region 10 and the amplifier region 12. As shown in FIG. 1, the heater 60 (resistor) is provided in the laser region 10, and is not provided in the amplifier region 12. The heater 60 heats the laser region 10.

As shown in FIG. 2A and FIG. 2B, the electrode 50 is provided on a surface of the substrate 30 opposite to the active layer 36. The electrode 50 is in contact with the bottom surface of the substrate 30 and is electrically connected to the substrate 30. The electrode 50 is formed of metal.

The electrode 52 is provided above the mesa 31 and on a surface of the contact layer 42 opposite to the cladding layer 40, and is in contact with the surface. A wiring layer 53 is provided on the electrode 52 and extends from the top of the mesa 31 to one trench 37 and to a position beyond the trench 37. The wiring layer 53 is in contact with the electrode 52 through the opening of the insulating film 54 above the mesa 31. The electrode 52 and the wiring layer 53 are electrically connected to the contact layer 42. The wiring layer 53 is provided on the insulating film 54 at locations other than the mesa 31, and is insulated from the semiconductor layers by the insulating film 54.

The electrode 52 is formed of metal, and is a stacked body in which, for example, a gold (Au) layer, a tin (Sn) layer, and an Au layer are stacked, in this order, on the contact layer 42. The wiring layer 53 is formed of, for example, Au.

As shown in FIG. 2B, the heater 60 is provided on the top surface of the insulating film 54 and is located above the mesa 31. A wiring layer 65 extends from the top of the mesa 31 to one trench 37 and to a position beyond one trench 37. The wiring layer 65 is provided on the top surface of the heater 60 above the mesa 31, and is provided on the top surface of the insulating film 54 outside the mesa 31. The heater 60 and the wiring layer 65 are insulated from the electrode 52, the wiring layer 53, and the semiconductor layers by the insulating film 54.

The heater 60 is formed of metal, and is a stacked body in which, for example, a platinum (Pt) layer, a titanium (Ti) layer, a tungsten (W) layer, and an alloy (TiW) layer of titanium and tungsten are stacked on the contact layer 42 in this order. The thickness of the heater 60 is, for example, 0.1 μm to 1.0 μm. The wiring layer 65 is formed of, for example, Au.

As shown in FIG. 1, the heater 60 has a portion 62 (first portion) and a portion 64 (second portion). The portion 62 is provided in the laser region 10 and extends in parallel to the X-axis direction. The portion 64 is provided in the laser region 10 and is located closer to the amplifier region 12 than the portion 62. The portion 64 is connected to the portion 62 and extends from a tip of the portion 62 to the boundary 13 in the X-axis direction.

A pad 56 is formed of the same metal layer as the wiring layer 65, and is electrically connected to the heater 60. One of the two pads 56 is connected to the portion 62. The other pad 56 is connected to the portion 64.

The planar shape of the portion 62 and the planar shape of the portion 64 of the heater 60 are rectangular. A width of the portion 62 in the Y-axis direction is defined as W1. A width of the portion 64 is defined as W2. The width W1 of the portion 62 is greater than the width W2 of the portion 64. A length of the portion 62 in the X-axis direction is defined as L3. A length of the portion 64 is defined as L4. The length L3 of the portion 62 is greater than the length L4 of the portion 64.

Since the portion 64 is thinner than the portion 62, the electrical resistance of the portion 64 per unit length is higher than the electrical resistance of the portion 62 per unit length. Since the portion 62 is longer than the portion 64, the overall electrical resistance of the portion 62 is higher than the overall electrical resistance of the portion 64.

The mesa 31 of the semiconductor laser device 100 includes the active layer 36. At a position overlapping the mesa 31, the n-type substrate 30 and the cladding layer 33, the i-type active layer 36, and the p-type cladding layer 40 and the contact layer 42 form a positive-intrinsic-negative (pin) junction. In a portion outside the mesa 31, the p-type cladding layer 40, the n-type semiconductor layer 46, the p-type semiconductor layer 44, and the n-type substrate 30 are stacked and form a pnpn junction. That is, a current confinement structure including the mesa 31 is formed. Current easily flows into the mesa 31, and is less likely to flow outside the mesa 31.

When a voltage is applied to the electrode 50 and the electrode 52, current selectively flows to the mesa 31. Carriers are injected into the active layer 36 and are combined, thereby generating light. The light propagates through the mesa 31 and is laser-oscillated at wavelength corresponding to the period of the diffraction grating 35. A laser beam is reflected from the high-reflection coating 14. The laser beam is amplified in the amplifier region 12, passes through the anti-reflection coating 16, and is emitted to the outside of the semiconductor laser device 100.

The semiconductor laser device 100 is a wavelength tunable laser device, and can change wavelength of emitted light. Current flows through the heater 60, and thus the heater 60 generates heat, and the laser region 10 is heated. The refractive index of the diffraction grating 35 changes in response to the change in temperature. The wavelength of the laser beam is changed.

As an example, it is assumed that the semiconductor laser device 100 is used for optical communication. The wavelength range of the emitted light is approximately 4.5 nm, from 1295.56 nm to 1300.05 nm. The wavelength of the laser beam changes by approximately 0.1 nm for a temperature change of 1 degree Celsius. In order to change the wavelength within the above range, it is required to have a temperature change within a range of 45 degrees Celsius, for example, from 30 degrees Celsius to 75 degrees Celsius.

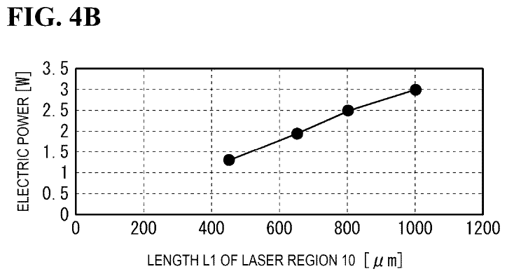

FIG. 4A is a diagram illustrating heating efficiency. The horizontal axis represents the length L1 of the laser region 10. The vertical axis represents the heating efficiency. The heating efficiency is a change in the temperature with respect to electric power input to the heater 60.

FIG. 4B is a diagram illustrating electric power. The horizontal axis represents the length L1 of the laser region 10. The vertical axis represents the electric power input to the heater 60 to change the wavelength by 4.5 nm. In this example, the amount of change in the wavelength per degree Celsius of temperature is 0.1 nm/° C., and the amount of change in the wavelength is 4.5 nm. To achieve a wavelength shift of 4.5 nm, the temperature is changed by 45 degrees Celsius. FIG. 4B shows the electric power required for a 45 degrees Celsius temperature change.

As the length of the laser region 10 is long, the heating efficiency decreases, resulting in an increase in the electric power required for the wavelength shift of 4.5 nm. As the length of the laser region 10 is short, the heating efficiency increases, resulting in a decrease in the electric power. In order to reduce the electric power, shorten the laser region 10 may be shortened. When the laser region 10 is too short, operation becomes unstable.

The semiconductor laser device 100 is designed in consideration of heating efficiency and electric power. For example, the length L1 of the laser region 10 is set to be 350 μm to 800 μm. The length L2 of the amplifier region 12 is set to be 200 μm to 1500 μm. The light can be laser-oscillated and the laser beam can be amplified. The length L3 of the portion 62 of the heater 60 is shorter than the length LI of the laser region 10, for example, 100 μm shorter than the length L1. The length L4 of the portion 64 of the heater 60 is, for example, 50 μm to 200 μm, and is smaller than the length L3 of the portion 62. The width WI of the portion 62 is, for example, 1.5 μm to 10 μm. The width W2 of the portion 64 is, for example, in a range of 1.5 μm to 10 μm, and is smaller than the width W1. The thickness of the heater 60 is, for example, 0.1 μm to 1.0 μm.

The wavelength is changed by heating the laser region 10. On the other hand, when the temperature of the amplifier region 12 rises, the output may decrease. By ensuring that only the laser region 10 is heated while the temperature of the amplifier region 12 is not increased, it is possible to achieve both wavelength change and high output power.

### Comparative Example

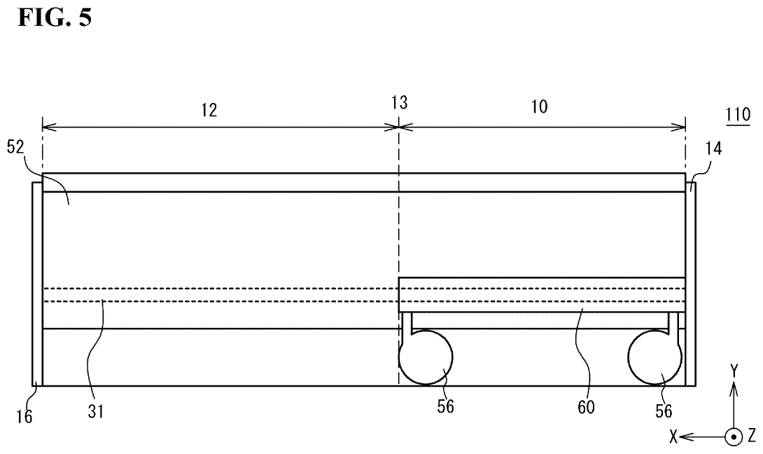

FIG. 5 is a plan view illustrating a semiconductor laser device 110 according to a comparative example. The heater 60 of the semiconductor laser device 110 has a constant width. The heater 60 is provided in the laser region 10.

### Temperature Distribution

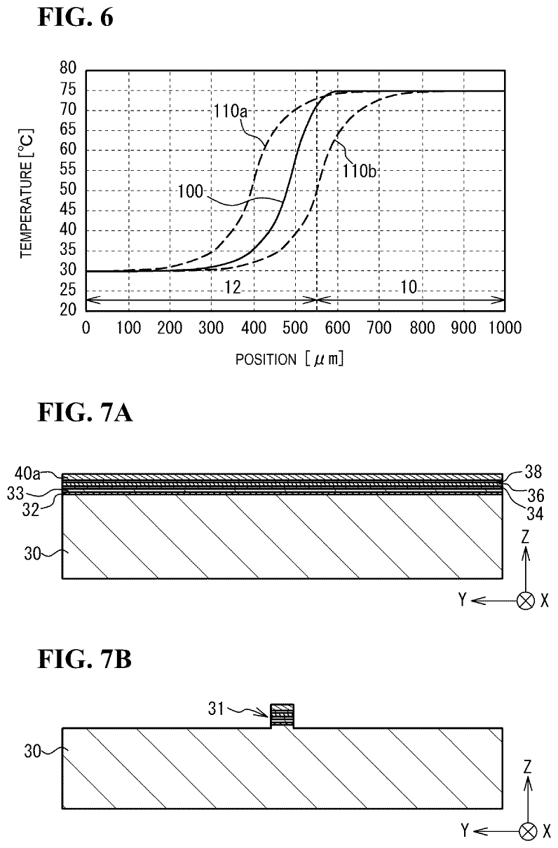

FIG. 6 is a diagram illustrating a temperature distribution. The horizontal axis represents the position of the semiconductor laser device in the X-axis direction. The thick dashed line represents the point at 550 μm. The positions from 0 μm to 550 μm correspond to the amplifier region 12. The positions from 550 μm to 1000 μm correspond to the laser region 10. That is, in this example, the length of the semiconductor laser device in the X-axis direction is 1000 μm, the length L2 of the amplifier region 12 is 550 μm, and the length L1 of the laser region 10 is 450 μm. The vertical axis of FIG. 6 represents the temperature. The temperature of the laser region 10 is raised from 30 degrees Celsius to 75 degrees Celsius.

In each of the comparative example and the first embodiment, the temperature distribution is calculated. Table 1 shows examples of the designs of the semiconductor laser devices used for the calculation of the temperature distribution.

TABLE 1

SEMICONDUCTOR LASER DEVICE

| | 110a | 110b | 100 |
|---|---|---|---|
| CURRENT[A] | 0.1 | 0.1 | 0.1 |
| L3 [μm] | 600 | 450 | 400 |
| W1 [μm] | 3.05 | 3.05 | 4.10 |
| L4 [μm] | | | 50 |
| W2 [μm] | | | 2.23 |
| R1 [Ω] | 205 | 155 | 102.5 |
| R2 [Ω] | | | 23.5 |
| V1 [V] | 20.5 | 15.5 | 10.25 |
| V2 [V] | | | 2.35 |
| P1 [W] | 2.05 | 1.55 | 1.025 |
| P2 [W] | | | 0.235 |

Table 1 shows design examples of a semiconductor laser device 110a, a semiconductor laser device 110b, and the semiconductor laser device 100 in order from the left. The semiconductor laser device 110a and the semiconductor laser device 110b correspond to the comparative example. In the semiconductor laser device 110a, the heater 60 protrudes to the amplifier region 12. In the semiconductor laser device 110b, the heater 60 extends to the boundary 13 between the laser region 10 and the amplifier region 12, and does not protrude to the amplifier region 12.

In each of the semiconductor laser device 110a and the semiconductor laser device 110b, the overall length of the heater 60 is defined as L3, the width of the heater 60 is defined as W1, and the electrical resistance of the heater 60 is defined as R1. The length L3 of the heater 60 in the semiconductor laser device 110a is 600 μm. The length L3 of the heater 60 in the semiconductor laser device 110b is 450 μm. In each of the semiconductor laser device 110a and the semiconductor laser device 110b, the width W1 of the heater 60 is 3.05 μm. The electrical resistance R1 of the heater 60 of the semiconductor laser device 110a is 205 Ω. A voltage V1 applied to the heater 60 of the semiconductor laser device 110a is 20.5 V, and the current flowing through the heater 60 is 0.1 A. An overall electric power PI consumed by the heater 60 of the semiconductor laser device 110a is 2.05 W. The electrical resistance R1 of the heater 60 of the semiconductor laser device 110b is 155 Ω. The voltage VI applied to the heater 60 of the semiconductor laser device 110b is 15.5 V, and the current flowing through the heater 60 is 0.1 A. The overall electric power Pl consumed by the heater 60 of the semiconductor laser device 110b is 1.55 W.

In the semiconductor laser device 100, the length L3 of the portion 62 of the heater 60 is 400 μm, and the width W1 of the portion 62 is 4.10 μm. The length L4 of the portion 64 of the heater 60 is 50 μm, and the width W2 of the portion 64 is 2.23 μm. The electrical resistance R1 of the portion 62 is 102.5 Ω, and an electrical resistance R2 of the portion 64 is 23.5 Ω. The voltage V1 applied to the portion 62 is 10.25 V, and a voltage V2 applied to the portion 64 is 2.35 V. The current of 0.1 A flows through the entire heater 60. The electric power P1 consumed by the portion 62 is 1.025 W. An electric power P2 consumed by the portion 64 is 0.235 W. The total value of the electric power consumption is 1.26 W.

In FIG. 6, the dashed lines indicate the calculation results of the comparative example (110a and 110b). The solid line indicates the calculation result of the semiconductor laser device 100 according to the first embodiment.

In the semiconductor laser device 110a, the heater 60 protrudes from the laser region 10 into the amplifier region 12. The entire laser region 10 can be uniformly heated to a temperature of approximately 75 degrees Celsius. However, a portion of the amplifier region 12 close to the laser region 10 is also heated, resulting in the temperature to rise. The optical output may decrease.

In the semiconductor laser device 110b, the heater 60 is provided only in the laser region 10. The temperature of the amplifier region 12 is less likely to rise. However, the temperature of the laser region 10 is not uniform. In a portion of the laser region 10 close to the amplifier region 12, the temperature does not reach the target value of 75 degrees Celsius. It is difficult to stably control the wavelength.

In the semiconductor laser device 100, the heater 60 has the portion 62 and the portion 64. The portion 64 extends to the boundary 13 between the laser region 10 and the amplifier region 12 and has the width W2 smaller than that of the portion 62. The resistance per unit length of the portion 64 is higher than the resistance per unit length of the portion 62. When current flows, the amount of heat generated per unit length of the portion 64 is greater than that of the portion 62. Thus, the portion provided with the portion 64 is heated more strongly than the portion provided with the portion 62.

As shown by the solid line in FIG. 6, a steep temperature distribution is obtained from the amplifier region 12 to the laser region 10. The temperature of almost the entire laser region 10 reaches the target value of 75 degrees Celsius. The temperature changes rapidly near the boundary between the laser region 10 and the amplifier region 12. The temperature of the amplifier region 12 is maintained at 45 degrees Celsius. It is possible to achieve both stable control of wavelength and high optical output.

### Manufacturing Method

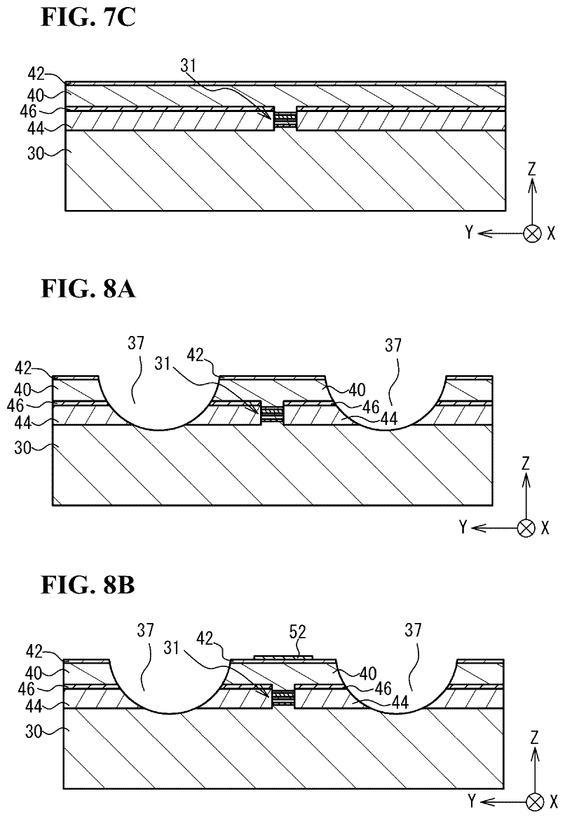

FIG. 7A to FIG. 9C are cross-sectional views each illustrating a manufacturing method of the semiconductor laser device 100, and each illustrating the laser region 10.

As shown in FIG. 7A, the semiconductor layer 32 is epitaxially grown on the top surface of the substrate 30 in the laser region 10 by metal organic chemical vapor deposition (MOCVD) method. The semiconductor layer 32 is formed into an island shape by etching. The cladding layer 33 is epitaxially grown so as to embed the semiconductor layer 32. The diffraction grating 35 of FIG. 2A is formed. In the laser region 10 and the amplifier region 12, the light confinement layer 34, the active layer 36, and the light confinement layer 38 are epitaxially grown in this order. A cladding layer 40a is epitaxially grown on the top surface of the light confinement layer 38.

As shown in FIG. 7B, the mesa 31 is formed by etching. The mesa 31 includes layers from the cladding layer 40a to a portion of the substrate 30. As shown in FIG. 7C, the semiconductor layer 44 and the semiconductor layer 46 are grown on both sides of the mesa 31. A p-type InP layer is epitaxially grown on the mesa 31 and the semiconductor layer 46. The InP layer and the cladding layer 40a form the cladding layer 40. The contact layer 42 is epitaxially grown on the top surface of the cladding layer 40.

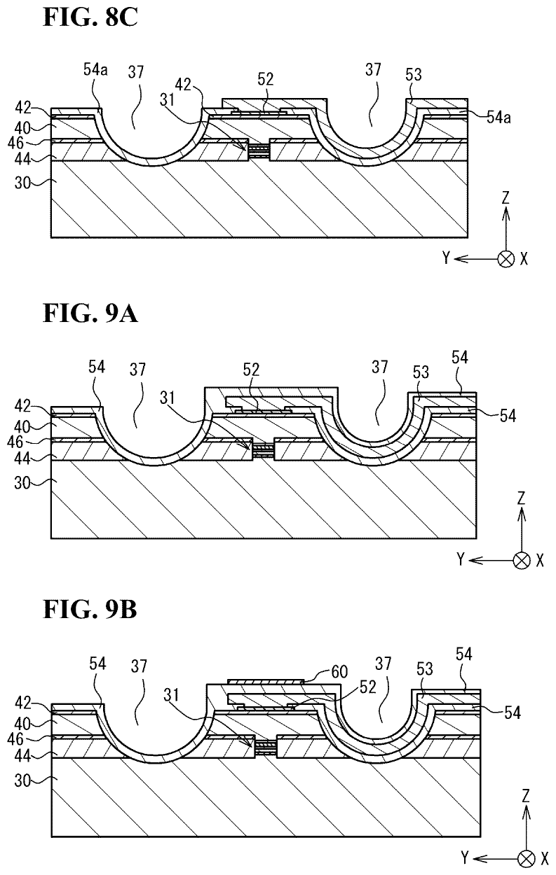

As shown in FIG. 8A, the contact layer 42 and the substrate 30 are etched partway on both sides of the mesa 31 to form trenches 37. As shown in FIG. 8B, the electrode 52 is formed on the top surface of the contact layer 42 of the mesa 31 by, for example, vacuum deposition and lift-off.

As shown in FIG. 8C, an insulating film 54a is deposited by, for example, a plasma enhanced CVD (PECVD) method. The insulating film 54a covers the mesa 31, the inside of the trench 37, and the contact layer 42 outside the trench 37. An opening is formed in the insulating film 54a above the mesa 31. For example, the wiring layer 53 is formed on the surfaces of the electrode 52 and the insulating film 54a by plating.

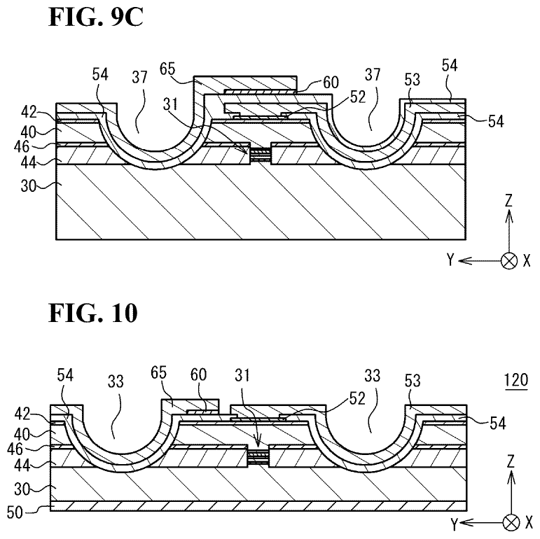

As shown in FIG. 9A, an insulating film is deposited to cover the insulating film 54a and the wiring layer 53. The deposited insulating film forms the insulating film 54 together with the insulating film 54a.

As shown in FIG. 9B, the heater 60 is formed on a surface of the insulating film 54 and above the mesa 31 by vacuum deposition and lift-off. As shown in FIG. 9C, the wiring layer 65 is formed by, for example, plating. After the substrate 30 is polished from the back surface, the electrode 50 is formed on the substrate 30. Thus, the semiconductor laser device 100 is formed.

According to the first embodiment, as shown in FIG. 1, the semiconductor laser device 100 includes the laser region 10 and the amplifier region 12. The heater 60 is provided in the laser region 10 and has the portion 62 and the portion 64. The portion 64 is located closer to the boundary 13 between the laser region 10 and the amplifier region 12 than the portion 62, and extends from the tip of the portion 62 to the boundary 13, for example. The width W1 of the portion 62 is greater than the width W2 of the portion 64. The electrical resistance per unit length of the portion 64 is higher than the electrical resistance per unit length of the portion 62. A portion of the laser region 10 near the boundary 13 is heated more strongly than a portion of the laser region 10 away from the boundary 13. Since the heater 60 is not provided in the amplifier region 12, the amplifier region 12 is less likely to be heated.

As shown in the example of FIG. 6, a steep temperature distribution is obtained. The temperature of the amplifier region 12 is low and is maintained at room temperature (for example, 30 degrees Celsius). The temperature rapidly rises from the amplifier region 12 to the boundary 13, and reaches 75 degrees Celsius. The temperature of almost the entire laser region 10 is higher than the temperature of the amplifier region 12, and is 75 degrees Celsius, for example. The wavelength of the laser beam can be changed by adjusting the temperature of the laser region 10 using the heater 60. Since the temperature of the amplifier region 12 is kept low, optical output is less likely to decrease. It is possible to control wavelength of light and improve optical output.

By changing the temperature by 45 degrees Celsius, the wavelength can be changed by 4.5 nm. The semiconductor laser device 100 can cover a band from 1295.5 nm to 1300.05 nm, for example. By controlling the wavelength with the heater 60, it is possible to compensate for the wavelength deviation between a plurality of chips. The electric power consumption for changing the temperature by 45 degrees Celsius is 1.26 W. The electric power consumption can be reduced as compared with the comparative example. The variable range of the temperature may be 45 degrees Celsius or more, or 45 degrees Celsius or less.

The width of the heater 60 changes discontinuously between the width W1 and the width W2. The electrical resistance also changes rapidly between the portion 62 and the portion 64. The design of the heater 60, the analysis of the temperature distribution, and the like are simplified. The width W1 of the portion 62 of the heater 60 is, for example, 4.10 μm. The width W2 of the portion 64 is, for example, 2.23 μm. The width W2 may be, for example, ½ times or more than the width W1, or ½ times or less than the width W1.

An end portion of the portion 64 is located at the boundary 13 between the laser region 10 and the amplifier region 12. Since the heater 60 is not provided in the amplifier region 12, the amplifier region 12 is less likely to be heated and the temperature is less likely to rise. Optical output can be increased. The heater 60 is provided in the laser region 10 from the boundary 13, and thus, the laser region 10 from the boundary 13 is heated. Since the temperature of the laser region 10 is changed, wavelength of light can be controlled.

As shown in FIG. 1, the portion 62 is longer than the portion 64. The portion 62 uniformly heats the portion of the laser region 10 away from the boundary 13. The short and thin portion 64 heats the portion of the laser region 10 near the boundary 13 more strongly. The temperature of the entire laser region 10 can be controlled to set wavelength to a desired value.

As shown in FIG. 2A, the substrate 30, the cladding layer 33, the active layer 36, the cladding layer 40, and the contact layer 42 are provided in the laser region 10 and the amplifier region 12. In the laser region 10, the semiconductor layer 32 is embedded in the cladding layer 33. A portion where the cladding layer 33, and the semiconductor layer 32 are alternately arranged functions as the diffraction grating 35. The temperature of the diffraction grating 35 can be changed by the heater 60. The refractive index of the diffraction grating 35 changes in response to the temperature change, and the oscillation wavelength of the light also changes.

As shown in FIG. 3, the mesa 31 includes the substrate 30, the cladding layer 33, and the active layer 36. The cladding layer 40 and the contact layer 42 are provided on or above the mesa 31. The heater 60 is provided above the contact layer 42 and directly above the mesa 31. In the portion interposed between the trenches 37, the width in the Y-axis direction can be decreased. The heater 60 is insulated from the electrode 52 and the semiconductor layers by the insulating film 54.

The n-type substrate 30 and the cladding layer 33, the i-type active layer 36, and the p-type cladding layer 40 and the contact layer 42 are stacked. A pin junction is formed. Carriers are injected into the active layer 36 by applying a voltage to the electrode 50 and the electrode 52. The active layer 36 generates light. The light propagates through the mesa 31. The wavelength of the laser beam is controlled by the diffraction grating 35 of the laser region 10. The laser beam is amplified in the amplifier region 12.

### Modification

FIG. 10 is a cross-sectional view illustrating a semiconductor laser device 120 according to a modification. The description of the same configuration as that of the first embodiment will be omitted. The heater 60 is located on the top surface of the insulating film 54, outside from just above the center of the mesa 31. The heater 60 is spaced apart from the wiring layer 53 and is not electrically connected. A film for insulation does not have to be provided. This reduces the number of processes.

### Second Embodiment

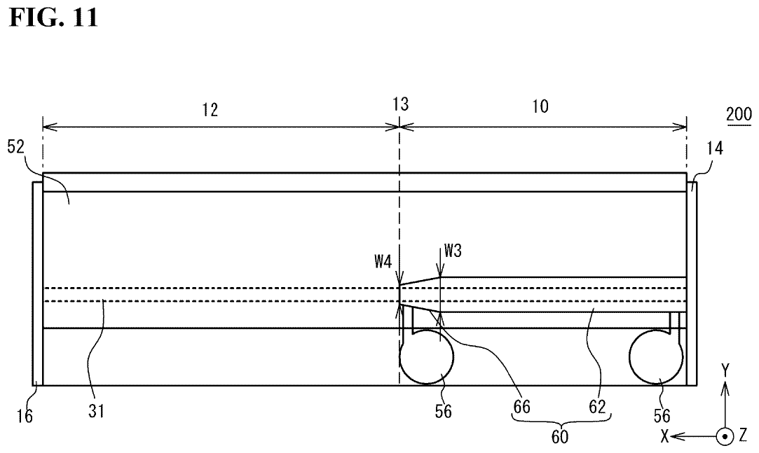

FIG. 11 is a plan view illustrating a semiconductor laser device 200 according to a second embodiment. The description of the same configuration as that of the first embodiment will be omitted. The heater 60 has the portion 62 (first portion) and a portion 66 (second portion). The portion 66 is connected to the portion 62 and is provided in a portion of the laser region 10 close to the boundary 13. A tip of the portion 66 is located at the boundary 13. The portion 66 has a tapered shape. The width of the portion 66 decreases as the distance from the portion 62 increases. A width W3 of the portion of the portion 66 which is in contact with the portion 62 is equal to the width W1 of the portion 62. A width W4 of the tip of the portion 66 is, for example, substantially the same as the width W2 of the portion 64 in FIG. 1.

According to the second embodiment, the portion 66 of the heater 60 is a tapered portion. The width of the portion 66 decreases as it gets closer to the boundary 13. The electrical resistance per unit length of the portion 66 is higher than the electrical resistance per unit length of the portion 62, and increases as the distance from the boundary 13 decreases. A portion near the boundary 13 is easily heated, and the temperature changes rapidly. Wavelength can be controlled and optical output can be improved.

The current density in the heater 60 changes continuously in the portion 66. The current is less likely to concentrate, and the heater 60 is less likely to burn.

### Third Embodiment

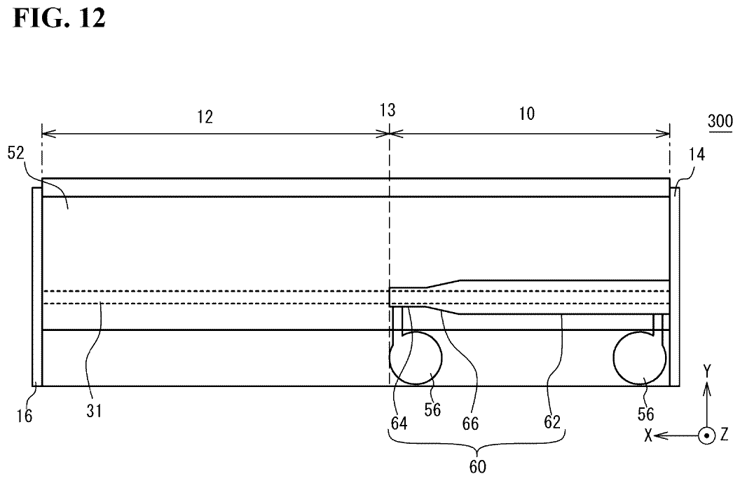

FIG. 12 is a plan view illustrating a semiconductor laser device 300 according to a third embodiment. The description of the same configuration as that of the first embodiment or the second embodiment will be omitted. The heater 60 has the portion 62 (first portion), the portion 64, and the portion 66 (these two are second portions). The portion 62, the portion 66, and the portion 64 are arranged in this order from the laser region 10 to the amplifier region 12. The portion 66 is connected to the tip of the portion 62. The portion 64 is connected to the tip of the portion 66. A tip of the portion 64 is located at the boundary 13.

According to the third embodiment, the heater 60 has the portion 62, the portion 64 and the portion 66. The electrical resistance per unit length of each of the portion 64 and the portion 66 is higher than the electrical resistance per unit length of the portion 62. The temperature changes rapidly near the boundary 13. It is possible to control wavelength of light and improve optical output.

The portion 66 is located between portion 62 and the portion 64, and has a tapered shape. Since the current density continuously changes in the portion 66, the heater 60 is less likely to break.

### Fourth Embodiment

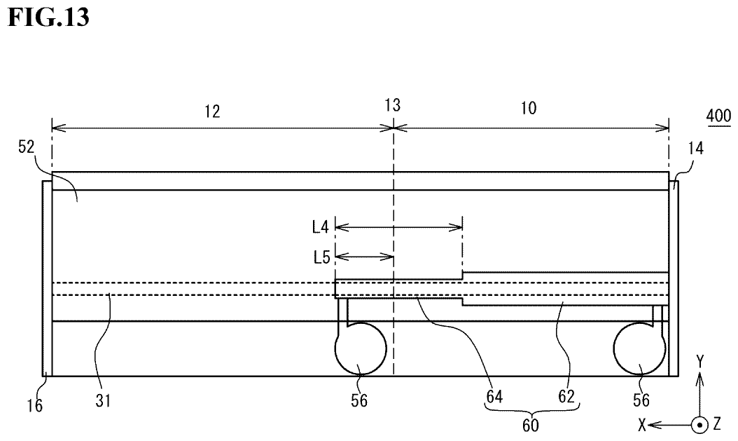

FIG. 13 is a plan view showing a semiconductor laser device 400 according to a fourth embodiment. The description of the same configuration as that of any one of the first embodiment to the third embodiment will be omitted. The heater 60 has the portion 62 and the portion 64. The portion 64 extends from laser region 10 into amplifier region 12. The tip of the portion 64 is located in the amplifier region 12. A length L5 of a portion of the portion 64 that is located in the amplifier region 12 may be, for example, equal to or more than half of the total length L4 of the portion 64 or equal to or less than half of the length L4.

According to the fourth embodiment, the portion 64 of the heater 60 is provided near the boundary 13 between the laser region 10 and the amplifier region 12. The portion 64 heats a portion of the laser region 10 close to the boundary 13. The temperature of the entire laser region 10 is uniformly changed by uniformly heating the laser region 10 by the heater 60. Wavelength of light can be controlled with high accuracy. The heater 60 is provided only in a portion of the amplifier region 12 close to the boundary 13. The temperature of the amplifier region 12 is less likely to rise. It is possible to control wavelength of light and improve optical output.

The heater 60 may have a tapered shape portion 66, and the portion 66 may be provided in the amplifier region 12. The heater 60 may have the portion 64 and the portion 66. The portion 66 or the portion 64 may protrude to the amplifier region 12.

### Fifth Embodiment

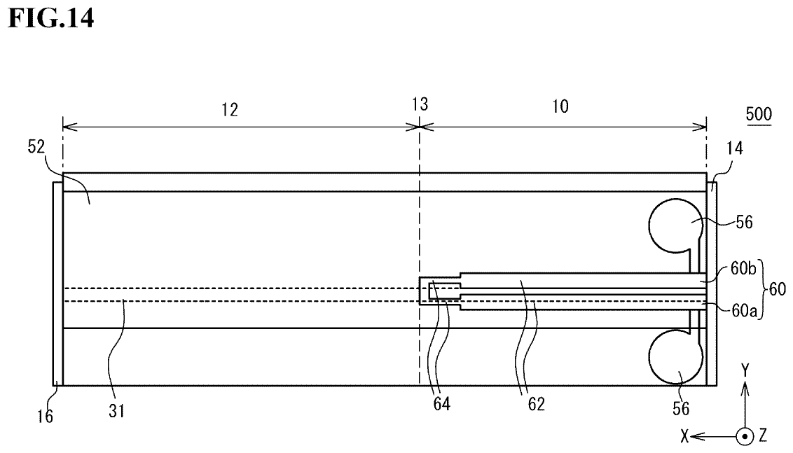

FIG. 14 is a plan view illustrating a semiconductor laser device 500 according to a fifth embodiment. The description of the same configuration as that of any one of the first embodiment to the fourth embodiment will be omitted. The heater 60 includes a heater 60a (resistor) and a heater 60b (resistor). The heater 60a is provided on the mesa 31. The heater 60b is provided at a position away from the mesa 31 in the Y-axis direction. The heater 60a and the heater 60b are connected to each other and have a shape that reciprocates in the X-axis direction. Each of the heater 60a and the heater 60b has the portion 62 and the portion 64. The portion 64 of the heater 60a and the portion 64 of the heater 60b are connected. The tips of the two portions 64 are located at the boundary 13.

According to the fifth embodiment, the heater 60 includes the heater 60a and the heater 60b. The wavelength of light can be controlled by efficiently changing the temperature of the laser region 10. The two portions 64 of the heater 60 are provided close to the boundary 13 in the laser region 10. The temperature changes rapidly near the boundary 13. It is possible to control wavelength of light and improve optical output. The heater 60 of the fifth embodiment is longer than the heater 60 of the first embodiment, for example, twice as long. The current flowing through the heater 60 is reduced.

At least one of the heater 60a or the heater 60b may include the portion 66. The portion 64 of the heater 60 may protrude to the amplifier region 12.

Although the embodiments of the present disclosure have been described in detail, the present disclosure is not limited to the specific embodiments, and various modifications and changes can be made within the scope of the gist of the present disclosure described in the claims.

What is claimed is:

1. A semiconductor laser device comprising:
a laser region configured to cause light to perform laser oscillation;
an amplifier region adjacent to the laser region and configured to amplify the light; and
a resistor provided in the laser region and configured to heat the laser region,
wherein the resistor has at least one first portion and at least one second portion,
wherein the at least one second portion is connected to the at least one first portion and is closer to a boundary between the laser region and the amplifier region than the first portion, and
wherein a resistance per unit length of the at least one second portion is higher than a resistance per unit length of the at least one first portion.

2. The semiconductor laser device according to claim 1,
wherein the at least one first portion has a width greater than a width of the at least one second portion.

3. The semiconductor laser device according to claim 1,
wherein the at least one second portion includes a tapered portion, and
wherein the tapered portion has a width that decreases from the laser region toward the amplifier region.

4. The semiconductor laser device according to claim 1,
wherein the at least one second portion is provided in the laser region, and
wherein the at least one second portion has an end portion located at the boundary between the laser region and the amplifier region.

5. The semiconductor laser device according to claim 1,
wherein the at least one second portion is provided in the laser region and the amplifier region.

6. The semiconductor laser device according to claim 1,
wherein the at least one first portion and the at least one second portion comprises two first portions and two second portions, respectively,
wherein one of the two first portions and one of the two second portions are connected to each other,
wherein the one of the two second portions and another one of the two second portions are connected to each other, and
wherein the another one of the two second portions and another one of the two first portions are connected to each other.

7. The semiconductor laser device according to claim 1,
wherein the at least one first portion is longer than the at least one second portion in an extending direction of the laser region.

8. The semiconductor laser device according to claim 1, further comprising:
a first semiconductor layer provided in the laser region and the amplifier region; and
a second semiconductor layer provided in the laser region and embedded in the first semiconductor layer,
wherein a portion in which the first semiconductor layer and the second semiconductor layer are alternately arranged is configured to form a diffraction grating.

9. The semiconductor laser device according to claim 8, further comprising:
an active layer stacked above the first semiconductor layer; and
a third semiconductor layer stacked above the active layer,
wherein the first semiconductor layer has a first conductivity type,
wherein the third semiconductor layer has a second conductivity type,
wherein the first semiconductor layer and the active layer are configured to form a mesa,
wherein the mesa extends to the laser region and the amplifier region,
wherein the third semiconductor layer is provided on the mesa, and
wherein the resistor is provided above the third semiconductor layer and at a position directly above the mesa or at a position away from the mesa.
